(19) United States
(12) Patent Application Publication
(10) Pub. No.: US 2023/0054616 A1
(43) Pub. Date: Feb. 23, 2023

(54) City Scale Modeling and Evaluation of Dedicated Lanes for Connected and Autonomous Vehicles

(71) Applicant: Ford Global Technologies, LLC, Dearborn, MI (US)

(72) Inventors: Richard Twumasi-Boakye, Taylor, MI (US); Shadi Djavadian, Dearborn, MI (US); James Fishelson, Ypsilanti, MI (US); Andrea Broaddus, Berkeley, CA (US); Yifan Chen, Ann Arbor, MI (US); Melissa Ruhl, Dearborn, MI (US); Archak Mittal, Canton, MI (US); Xiaolin Cai, Ann Arbor, MI (US)

(73) Assignee: Ford Global Technologies, LLC, Dearborn, MI (US)

(21) Appl. No.: 17/405,623

(22) Filed: Aug. 18, 2021

(51) Int. Cl. B60W 40/09; G05B 13/04; B60W 60/00; B60W 40/06

(52) U.S. Cl. CPC B60W 40/09; G05B 13/048; B60W 60/001; B60W 40/06; B60W 2552/53; B60W 2540/30

(57) ABSTRACT

An agent-based model (ABM) is generated—the ABM comprises agents. The ABM includes a road network corresponding to a metropolitan geographical area of interest. The ABM can be executed to simulate behavior of the agents. The ABM includes a road network having designations of dedicated connected autonomous vehicle (CAV) lanes. The ABM further includes a CAV lane-choice behavior model that models CAV lane-choice behavior of drivers. The CAV lane-choice behavior model has parameters that can be varied to vary lane choice behavior modeled by the lane-choice behavior model. The lane-choice behavior model is applied to the ABM so that when the ABM is executed the agents behave at least in part according to the CAV lane-choice behavior model.

### BACKGROUND

The increasing use of connected autonomous vehicles (CAVs) as well as increasing traffic on road networks raises the importance of optimizing the design of lanes dedicated to CAVs and optimizing CAV services such as autonomous vehicle (AV) bus rapid-transit (BRT), AV demand-responsive transit (DRT), and the like. However, the multitude of factors that bear on such optimizing, as well as the complexity of their interactions, make optimizing dedicated CAV lanes and CAV services difficult. Although transportation systems have previously been computer-modeled for optimization, such models have not attempted to take into account factors relevant to CAV services and dedicated CAV lanes. Moreover, previous transportation system models have not been efficient enough to allow rapid design-of-experiment (DOE) methodologies to be used. That is, previous transportation system models have been highly compute-intensive and too slow to allow rapid experimentation through modeling. It has not previously been possible to use transportation models to experimentally identify optimal designs and user's choice of dedicated lanes for CAV services.

### BRIEF DESCRIPTION OF THE DRAWINGS

The present description will be better understood from the following detailed description read in light of the accompanying drawings, wherein like reference numerals are used to designate like parts in the accompanying description.

FIG. 1 shows a lane-choice behavior model incorporated into a mesoscopic city-scale agent-based model (ABM) in accordance with one or more embodiments of the disclosure.

FIG. 2 shows a process for constructing the mesoscopic city-scale ABM to include CAV-related features in accordance with one or more embodiments of the disclosure.

FIG. 3 shows an overview for designing models described herein in accordance with one or more embodiments of the disclosure.

FIG. 4 shows additional details of the general modeling framework in accordance with one or more embodiments of the disclosure.

FIG. 5 shows a framework for CAV integration in accordance with one or more embodiments of the disclosure.

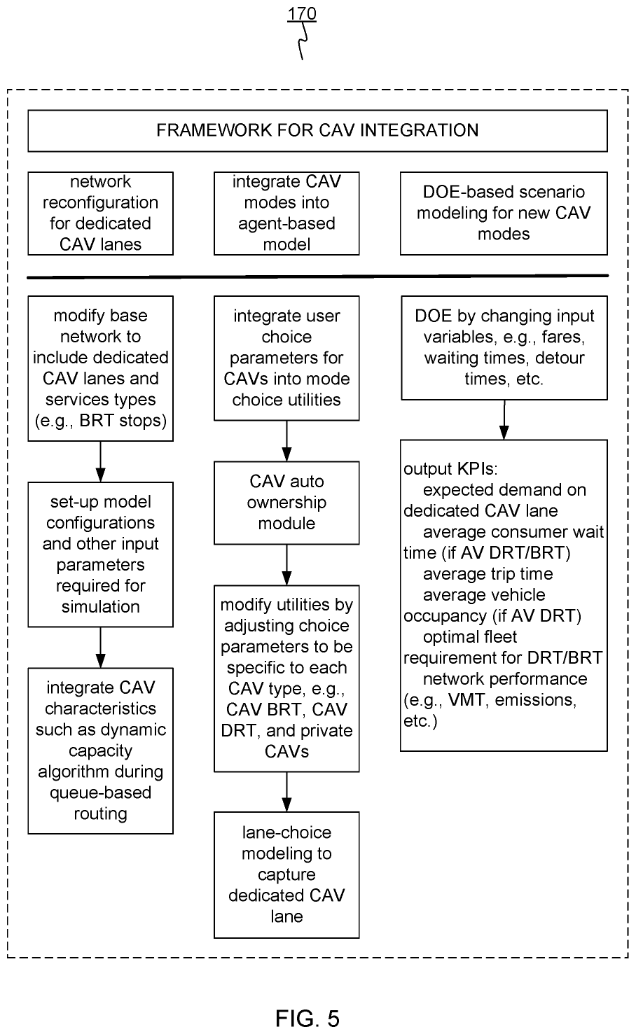

FIG. 6 shows functions performed by a platform for converting network data in accordance with one or more embodiments of the disclosure.

FIG. 7 shows functions performed by a platform for converting demand data in accordance with one or more embodiments of the disclosure.

FIG. 8 shows factors related to CAV-lane decision making in accordance with one or more embodiments of the disclosure.

FIG. 9 shows an architecture for modeling lane choice behavior of travelers in accordance with one or more embodiments of the disclosure.

FIG. 10 shows a process for collecting, processing, and parametrically adjusting CAV lane-choice data in accordance with one or more embodiments of the disclosure.

FIG. 11 shows model input data from user surveys in accordance with one or more embodiments of the disclosure.

FIG. 12 shows formulas that may be used by the lane-choice model to predict probabilities of choosing a regular lane or a CAV lane in accordance with one or more embodiments of the disclosure.

FIG. 13 shows a method for integrating a CAV mode to evaluate the attractiveness of a CAV lane in accordance with one or more embodiments of the disclosure.

FIG. 14 shows details of a computing device 400, one or more of which may execute the tools and models/simulations discussed above.

### DETAILED DESCRIPTION

### Overview

An agent-based model (ABM) is generated, where the ABM comprises agents. The ABM includes a road network corresponding to a metropolitan geographical area of interest. The ABM can be executed to simulate behavior of the agents. The ABM includes a road network having designations of dedicated connected autonomous vehicle (CAV) lanes. The ABM further includes a CAV lane-choice behavior model that models CAV lane-choice behavior of drivers. The CAV lane-choice behavior model has parameters that can be varied to vary lane choice behavior modeled by the lane-choice behavior model. The lane-choice behavior model is applied to the ABM so that when the ABM is executed the agents behave at least in part according to the CAV lane-choice behavior model.

### Illustrative Embodiments

As mentioned in the Background, there is a need for transportation models that allow rapid simulation of transportation networks with dedicated CAV lanes and CAV services. Many transportation experts expect that the influx of CAVs will result in improved traffic flow patterns. However, there are questions on how infrastructure changes and different CAV services can influence users' preferences. The strategic orchestration of CAVs in existing traffic is important for both improving traffic performance and users' choices of CAVs. One method of maximizing the benefits of CAVs is through a dedicated lane implementation for CAVs and its related services, e.g., AV BRT, AV DRT, etc.

One possible approach is to leverage microscopic traffic simulation. However, the computational requirements and run times of simulations do not allow for rapid prototyping of CAV services at city scales. Additionally, most microscopic simulation frameworks cannot help us understand (and do not account for) user's lane choice preferences when it comes to dedicated CAV lanes.

Following is a discussion of the lane-choice problem. As a new form of infrastructure, dedicated CAV lanes may borrow from existing options (i.e., high-occupancy toll lanes, bus rapid transit, toll lanes, and more), but this approach comes with challenges. Different features will impact “lane choice,”, that is, whether or not a person chooses to take the dedicated lane. Examples of such features include relative costs, benefits from platooning and signal priority, entry points, benefits of connectivity for travel time, travel reliability, and “freed” time from autonomy, and more.

Mesoscopic (and activity-based) models present a framework for city-scale modeling that account for agents' choices and have potential to realistically represent traffic system with simulation performance being closer to that of microsimulations. In mesoscopic traffic simulations, vehicles are modeled either as platoons on a link or with simplified vehicle dynamics. Previous models and tools in this domain may consider CAVs (e.g., Argonne's POLARIS) overall performance characteristics and mode choice. However, these previous tools are weak with respect to the relationship between the infrastructure and CAVs, especially where CAV behavior and rules may differ from traditional vehicles. In sum, no previous tool has had the ability to model dedicated CAV lane choice.

Understanding users' perceptions of dedicated CAV lanes and the main indicators of CAV lane choices can support business decisions and future investments in such infrastructural changes. These indicators can be integrated into models for scenario analysis using experimental design methods to estimate demand along a CAV-dedicated lane or corridor. Embodiments described herein may fill this gap by enhancing mesoscopic agent-based models (ABM) with information relevant to users' dedicated CAV lane choice.

Some embodiments described herein entail novel techniques and schema for discretizing demand data from trip-based travel demand models into inputs that can be provided to mesoscopic ABMs. These techniques may enable rapid development of mesoscopic ABMs in terms of data conversion platforms for network development and demand, among other things. Embodiments may also include techniques to develop a structured and scalable approach using network thinning methods for wide area traffic simulation by developing subareas of different network fidelities to allow detailed yet efficient simulation of areas of interest in various regions. For example, road network (“network” hereafter) attributes may be built by redefining roadways as dedicated to CAVs (dedicated corridors) with additional features for BRT) stops, and by representing different CAV service types (e.g., private car, BRT, demand-responsive transit, first mile/last mile shuttle, etc.) in the ABM framework. To these ends, frameworks may be developed for dedicated CAV lane-choice models that can be applied to ABMs. By varying the parameters in these lane-choice models, modelling experiments can be designed to understand constraints that facilitate users' adoption of dedicated CAV lanes, thus optimizing CAV corridor usage and performance along the dedicated corridor.

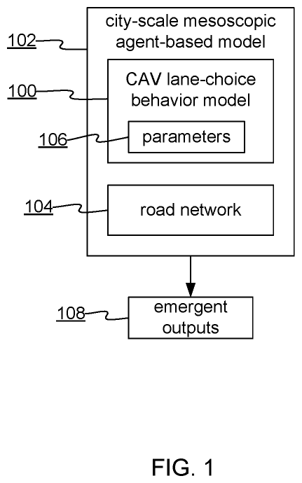

FIG. 1 shows a lane-choice behavior model 100 incorporated into a mesoscopic city-scale ABM 102. The mesoscopic city-scale ABM 102 also includes a network 104. The lane-choice behavior model 100 has parameters 106 that can be varied, which in turn varies the emergent outputs 108 outputted by the mesoscopic city-scale ABM 102 when simulations are run. The emergent outputs 108 can be used to inform designs of the modeled network and CAV services.

In review, ABMs are a class of models for simulating the actions and interactions of autonomous agents for the purpose of understanding their system-wide effects. An ABM can provide insights into the collective behavior of the modeled agents, which generally obey and act up one rules. An ABM simulates the simultaneous operations and interactions of its agents. Potentially complex information about the system as a whole emerges from the simulation of the actions of the agents. That is, high-level system properties emerge from the interactions of low-level subsystems. Often, simple behaviors (agent rules) generate complex behaviors that translate to state changes at the system level. In addition to agents/rules, ABMs may have decision-making heuristics, learning rules or adaptive processes, an interaction topology (e.g., a network), and an environment. ABMs are implemented as computer simulations, either as custom software, or via ABM toolkits. This software can be used to test how changes in individual behaviors will affect the system's emerging overall behavior. Because ABMs are known in the field of computing, some details of the mesoscopic city-scale ABM 102 are omitted. As discussed below, the lane-choice behavior model 100 informs the decisions and actions of the individual agents in the mesoscopic city-scale ABM 102.

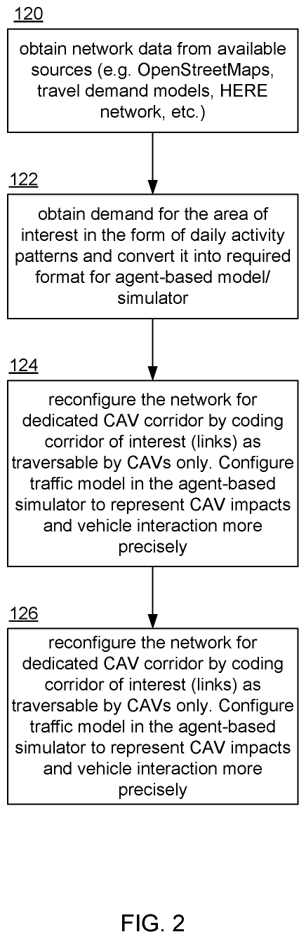

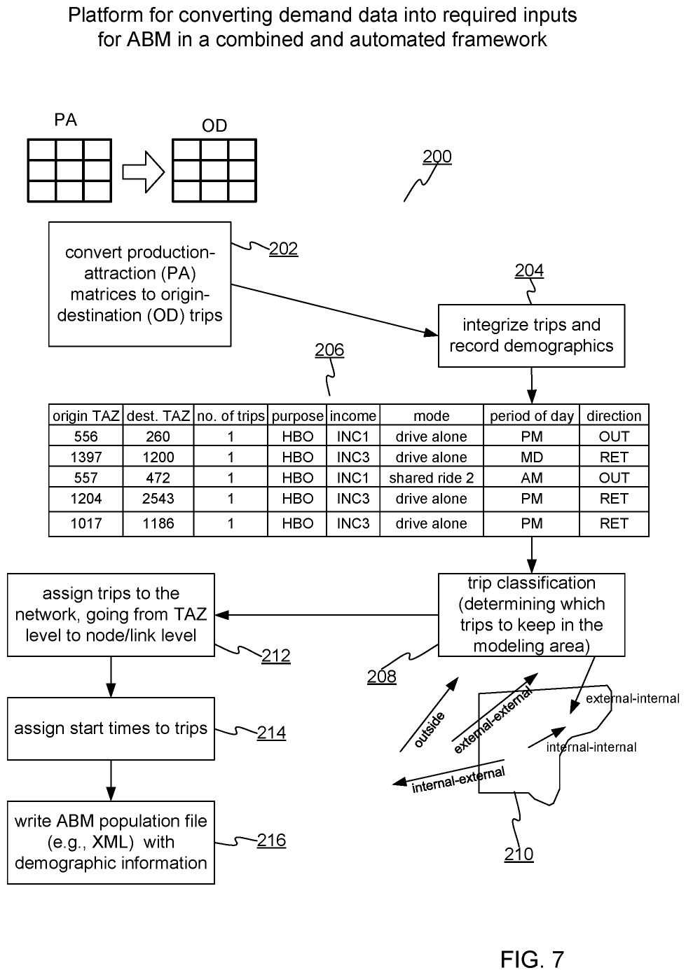

FIG. 2 shows a process for constructing the mesoscopic city-scale ABM 102 to include CAV-related features. At step 120, initial network data for the network 104 is obtained, for example one or more maps from the OpenStreetMap project, travel demand models, the HERE network (see here-dot-com), or other sources. Step 120 may include thinning the initial network to only retain fidelity for areas of interest, which may be performed using available geographic information system (GIS) tools. This step may significantly improve simulation runtimes of the mesoscopic city-scale ABM 102 (see FIG. 7). Also, at step 120, the final network may be converted to a format required for whichever agent-based simulator is used (the agent-based simulator executes the mesoscopic city-scale ABM 102). A platform with enhanced network editing features may be developed and used for rapidly converting network files from multiple network data sources into required inputs for mesoscopic models (see FIG. 7).

At step 122, demand data for the area of interest is obtained. The demand data is in the form of daily activity/travel patterns. The demand data is converted into whichever format is required by the agent-based simulator. In some implementations, the demand data may already in the required format. Otherwise, the demand data from travel-demand models or other data sources (in the form of production-attraction matrices or origin-destination matrices) is converted into individual agents with plans (origin, destination, start time, mode of travel, travel purpose, etc.), which is used as input for the mesoscopic city-scale ABM 102. This conversion process can be laborious, and the conversion platform discussed below with reference to FIG. 7 is also novel.

At step 124, the network is reconfigured for dedicated CAV corridors by coding corridors of interest (links) as traversable by CAVs only. The traffic model in the agent-based simulator is configured to precisely represent CAV effects and vehicle interactions. More detailed or advanced models may be used to capture (as proxies) lane-level details in the mesoscopic city-scale ABM 102. In addition, dynamic link capacity may be adjusted based on network links for different penetration rates of CAVs on roads in the network.

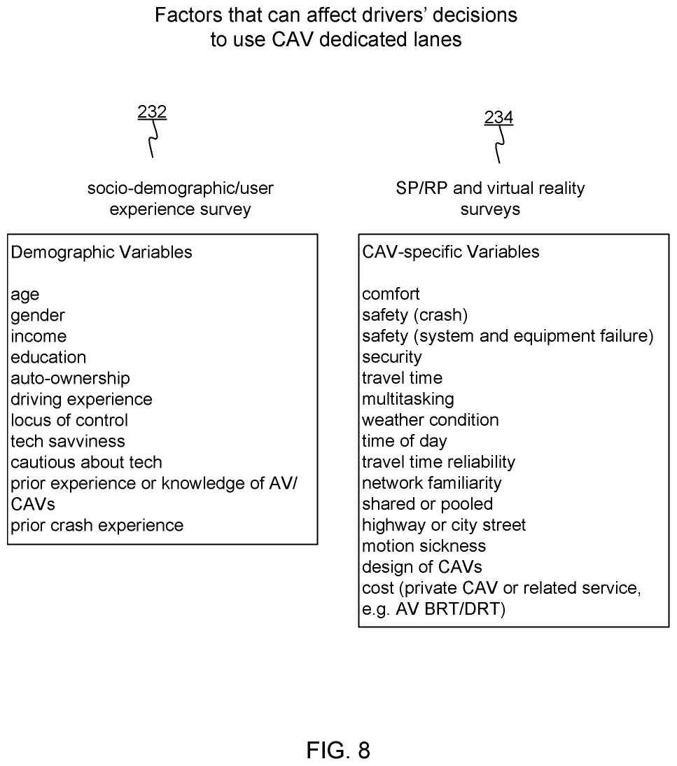

At step 126, modules for CAV modes with dedicated CAV lanes are developed and integrated. The CAV modes may include, but are not limited to, CAV BRT, CAV DRT, regular DRT, and multimodal trip-making (first mile/last mile). For new transit modes, fares may be set, and costs may be assigned to modes to designated links with stops. Other constraints may be set, for instance on vehicle size, maximum detour and waiting times, and alighting/boarding times (especially in the case of DRT). Pick-up and drop-off points may also be assigned. Moreover, as discussed below with reference to FIGS. 8-11, methods may be employed for collecting and integrating user-specific data into the CAV lane-choice behavior model 100 to generate insights on factors that influence users' CAV lane choices. These insights can inform decisions on investing in dedicated CAV lanes as well as which features on the lanes are most relevant to lane users.

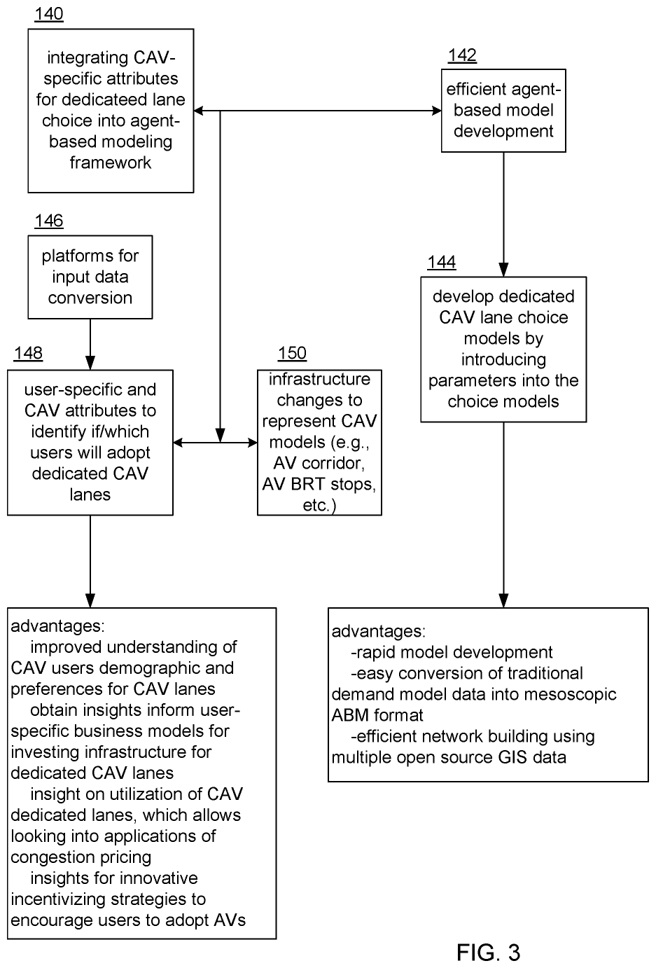

FIG. 3 shows an overview for designing models described herein. At step 140, CAV-specific attributes for dedicated CAV lane-choice are integrated into the lane-choice behavior model 100. At step 142, using tools described herein for efficiency, the mesoscopic city-scale ABM 102 is developed. At step 144, the CAC-lane-choice model 100 is incorporated into the ABM and the dedicated CAV lane-choice model 100 is further refined by introducing the parameters 106 into the choice models. Platforms 146 for input data conversion, as discussed above, are employed to generate user-specific and CAV attributes 148 that help identify if and/or which users are likely to adopt dedicated CAV lanes. At step 150, infrastructure changes to represent CAV models and services (e.g., AV corridor, AV BRT stops, etc.) are introduced. Potential advantages stemming from models built per steps 140, 142, 148, and 150 may include: improving understanding of CAV user demographics and preferences for CAV lanes; obtaining insights that inform user-specific business models for investing in infrastructure for dedicated CAV lanes; obtaining insights on utilization of dedicated CAV lanes, which may enable investigations into applications of congestion pricing; and understanding innovative ways to incentivize strategies to encourage users to adopt AVs. Potential advantages from steps 140, 142, and 144 may include: rapid model development; convenient conversion of traditional demand model data into a mesoscopic ABM format; and efficient network building using multiple open-source GIS data.

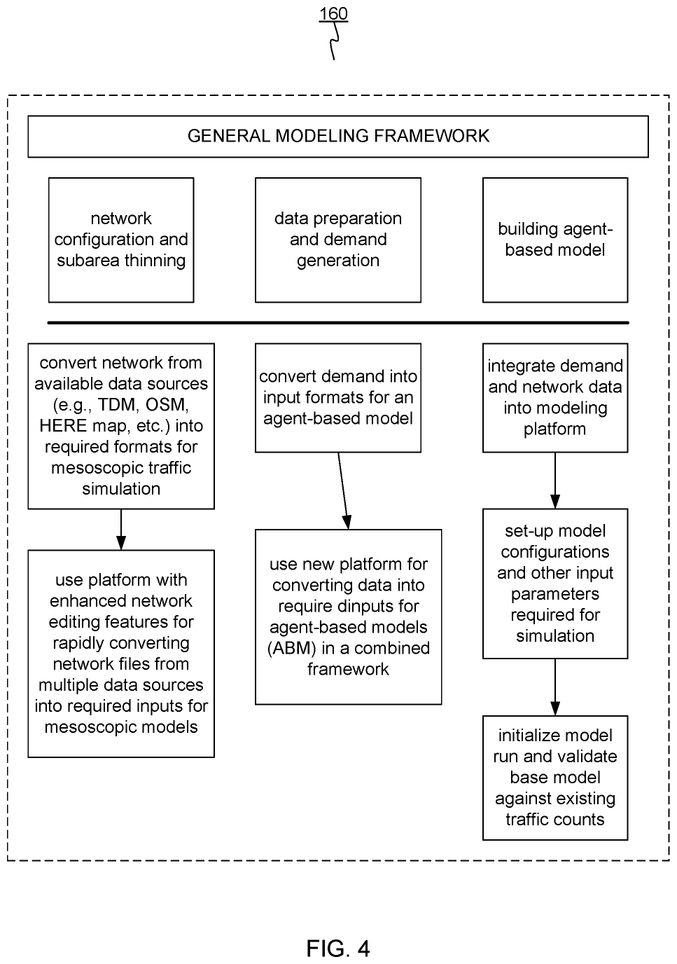

FIG. 4 shows additional details of the general modeling framework. For the task of network configuration and subarea thinning (left column), steps may include first converting network data from available data sources such as travel demand models (TDM), open street maps (OSM), HERE map, etc. into required formats for mesoscopic traffic simulation. Then, the platform with enhanced network editing features is used to rapidly convert network files from possibly multiple data sources into inputs required for mesoscopic models.

For the task of preparing and generating demand data (middle column), first, demand data is converted into input formats for an ABM. Then, the new platform is used to convert the demand data into inputs for an ABM in a combined framework.

For the task of building the mesoscopic city-scale ABM 102, first the prepared demand data and network data are incorporated into the modeling platform. Then, model configurations and other input parameters required for simulation are set-up. Finally, the mesoscopic city-scale ABM 102 is initialized and run to obtain results for the base model. The model run also allows for validating the base model against observed modal splits and existing traffic counts to ensure that output traffic patterns are with acceptable margin of error from ground truth.

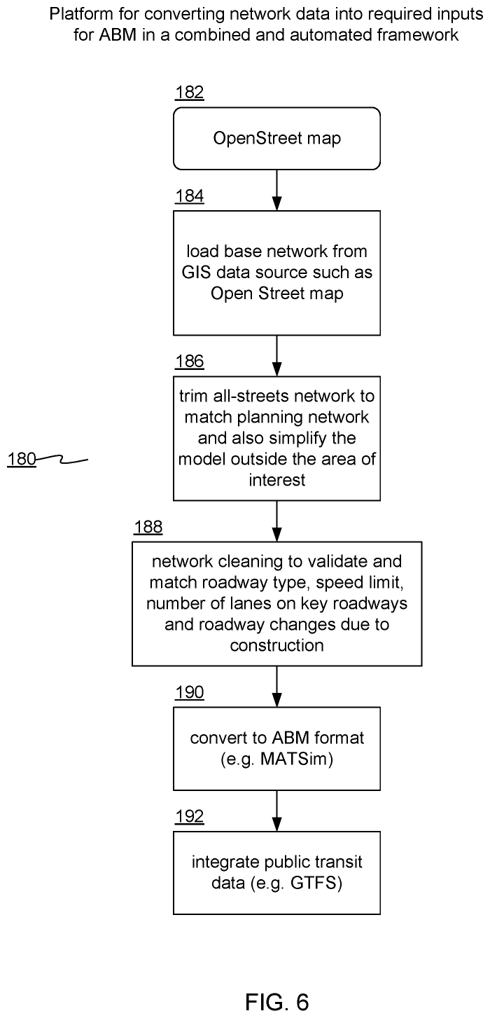

FIG. 6 shows a framework for CAV integration 170. The network is reconfigured for dedicated CAV lanes (left column). This may involve modifying the base network to include dedicated CAV lanes and services types (e.g., BRT stops). Then, model configurations and other input parameters required for simulation are set up. CAV characteristics such as dynamic capacity algorithm during queue-based routing are integrated into the model. CAV modes are integrated into the mesoscopic city-scale ABM 102 (middle column). This step may start with integrating user choice parameters for CAVs into mode choice utilities. A CAV auto ownership module is then added. Then, utilities are modified by adjusting choice parameters to be specific to each CAV type, e.g., CAV BRT, CAV DRT, and private CAVs. Finally, lane-choice modeling is performed to capture dedicated CAV lane data (right column). That is, the finally constructed mesoscopic city-scale ABM is executed (simulations are run) to determine key performance indicators (KPIs) within the model and its data. Specifically, a design-of-experiment (DOE) process is performed by changing input variables, e.g., fares, waiting times, detour times, etc. Emergent outputs for a CAV lane may include KPIs such as: expected demand on the dedicated CAV lane, average user wait time (if the lane is for CAV DRT/BRT), average trip time, average vehicle occupancy (if CAV DRT), optimal fleet requirement for CAV DRT/BRT, network performance (e.g., vehicle miles traveled, emissions, etc.).

FIG. 6 shows functions performed by a platform for converting network data 180 into required inputs for an ABM in a combined and automated framework. An initial network 182 is loaded at step 184, for instance a network/map from OpenStreetMap or another GIS data source. At step 186, the all-streets network is trimmed with network feature extraction scripts (the trimming and simplifying can be manual or automated using customized scripts) to match the planning network (the area/city of interest) and to simplify the model in the area surrounding the area of interest. At step 188 the network is cleaned to validate and match roadway type, speed limit, number of lanes on key roadways, and roadway changes due to construction. At step 190 the cleaned and validated network is converted to an ABM format (e.g., MATSim format). Finally, at step 192, public transit data such as General Traffic Feed Specification (GTFS) data is integrated into the network.

FIG. 7 shows functions performed by a platform for converting demand data 200 into required inputs for an ABM in a combined and automated framework. At step 202 production-attraction (PA) matrices are converted to origin-destination (OD) trips. At step 204 trips are integrized and demographic data is added, producing trip data 206. Regarding the former, some forms of demand data comprise statistical summaries of trips, which are converted into discrete (integer) trip counts. At step 208 trip records in the trip data 208 are classified to determine which trips to keep, i.e., which trips start and/or end within the area of interest 210 that is being modeled. At step 212, trips area assigned to the network, going from traffic analysis zone (TAZ) level to the node/link level. At step 214 trip start times are assigned, e.g., day or night. At step 216 an ABM population file including demographic information is written, e.g., in XML. The XML file may conform to a MATSim population schema such as version 6.

Nodes in the XML file might include a population node containing person nodes. Each person node might include attributes such as income, trip class, automobile availability, whether the person is a freight carrier, etc. Each person node may also have a plan node. Each plan node may an activity node, a leg mode, and an activity node, to name some examples. Each activity node may have attributes such as a trip type (e.g., home, work), a link identifier in the network, start or end time, geographical or map coordinates, etc. Each leg node may have attributes associated with a leg of a trip, for instance the mode of transport (e.g., car).

FIG. 8 shows factors related to CAV-lane decision making. As noted, the lane-choice behavior model 100 aims to model how drivers make lane choices. Two types of factors or variables bearing on this decision making may be included in the lane-choice behavior model 100 based on corresponding types of user surveys. Demographic variables 230 may include age, gender, income, education, auto-ownership, driving experience, locus of control, tech savviness, cautiousness about tech, prior experience or knowledge of AV/CAVs, prior crash experience, and the like. CAV-specific variables 232 may include comfort, vehicle crash rating, vehicle component wear (including typical systems and equipment life cycles), security, travel time, multitasking, weather condition, time of day, travel time reliability, network familiarity, shared or pooled, highway or city street, motion sickness, design of CAV, cost (private CAV or related service, e.g., AV BRT/DRT), and so forth.

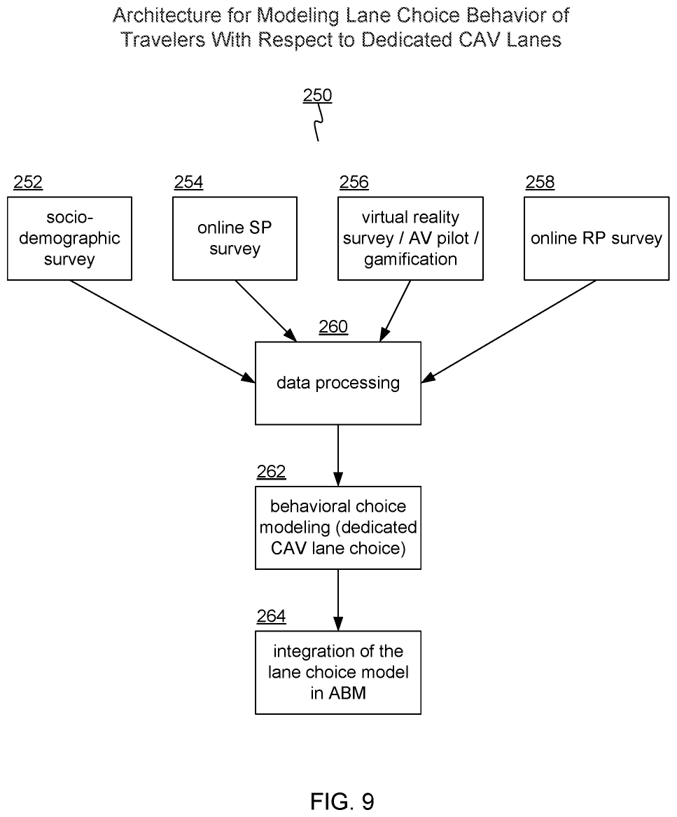

FIG. 9 shows an architecture 250 for modeling lane choice behavior of travelers with respect to dedicated CAV lanes. As noted, socio-demographic surveys 252 may be collected. Online stated preference (SP) surveys 254 may be collected. Data from users using a virtual reality simulator 256 may also be gathered. An online revealed preference (RP) survey 258 may also be taken. This data bearing on lane-choice behavior is processed at step 260 into a coherent format. At step 262 the lane choice data is used to model the behavior of choosing dedicated CAV lanes, i.e., the lane-choice behavior model 100 is constructed. At step 264 the lane-choice behavior model 100 is incorporated into the mesoscopic city-scale ABM model 102.

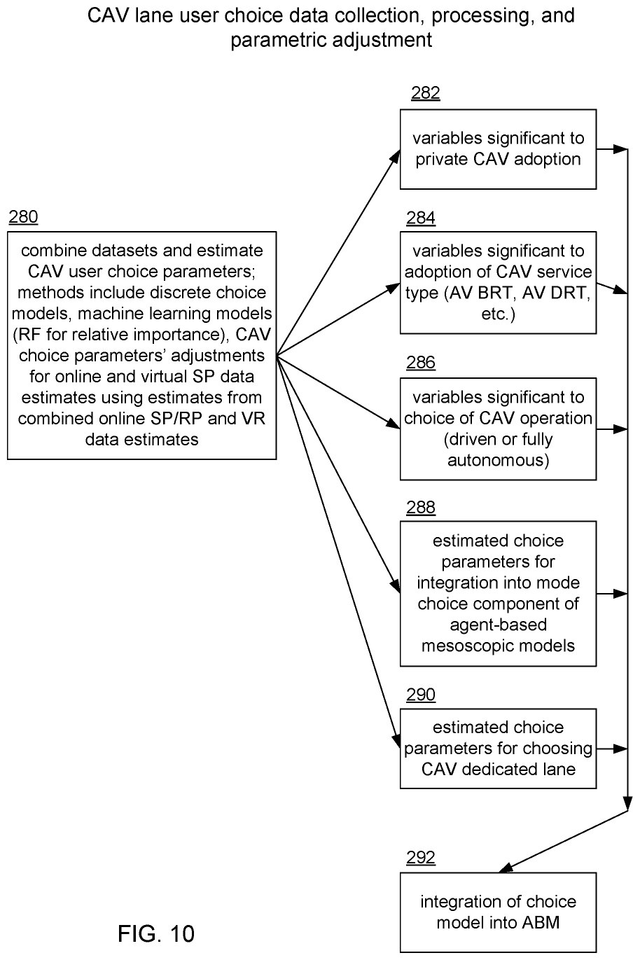

FIG. 10 shows a process for collecting, processing, and parametrically adjusting CAV lane-choice data. A verification module 280 combines datasets and CAV user choice parameters are estimated. The verification module 280 may include discrete choice models, machine learning models (RF for relative importance), etc. The verification module 280 may also perform CAV choice parameters' adjustments for online and virtual SP data estimates using estimates from combined online SP/RP and VR data estimates, discussed above. The verification module 280 outputs variables significant to private CAV adoption 282, variables significant to adoption of CAV service type (AV BRT, AV DRT, etc.) 284, variables significant to choice of CAV operation (driven or fully autonomous) 286, estimated choice parameters for integration into mode choice component of agent-based mesoscopic models 288, and, of note, estimated choice parameters for choosing CAV dedicated lane 290. At step 292 the variables of the lane-choice behavior model are integrated into the mesoscopic city-scale ABM 102.

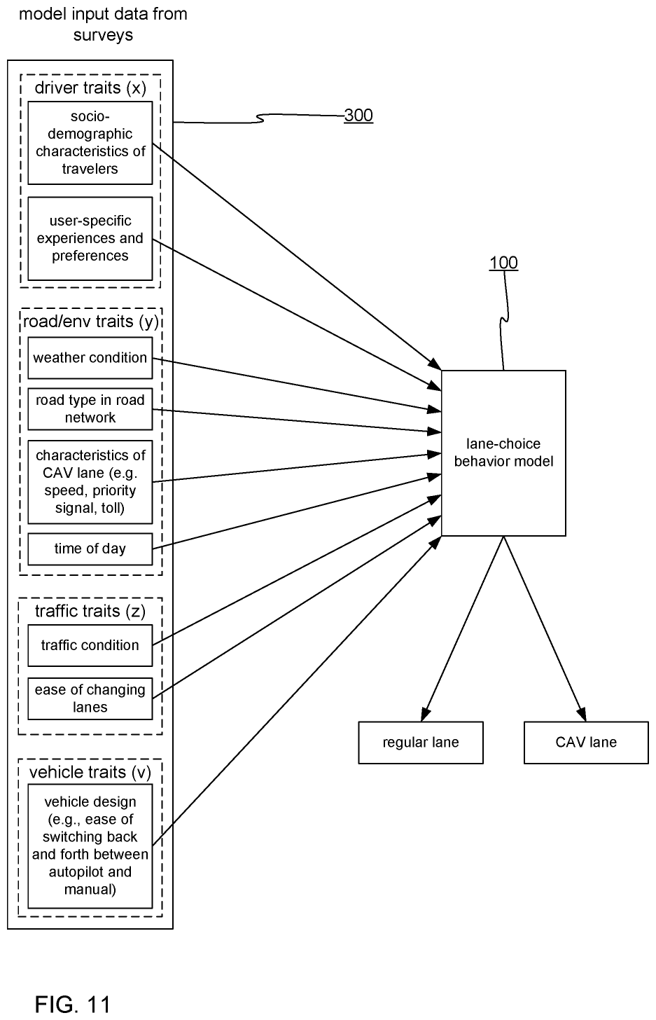

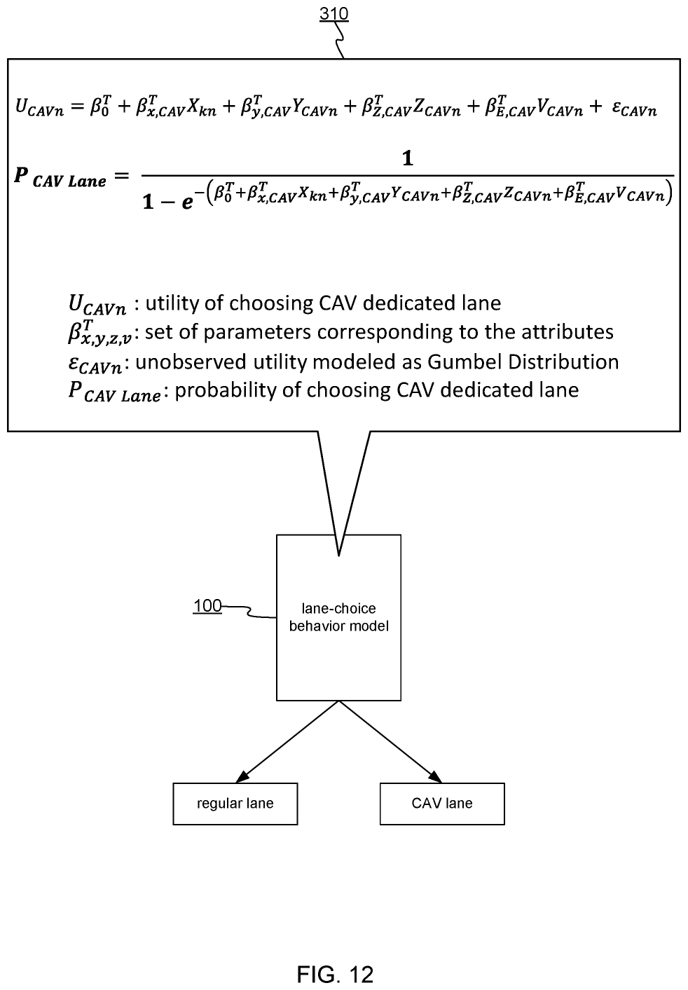

FIG. 11 shows model input data 300 from user surveys. The input data includes driver traits (x), road/env traits (y), traffic traits (z), and vehicle traits (v). The lane-choice behavior model 100 outputs probabilities that a user chooses a regular lane or a CAV lane on any particular trip. FIG. 12 shows formulas that may be used by the lane-choice model 100 to predict probabilities of choosing a regular lane or a CAV lane. As can be seen, the input data serves as parameters for an example function that computes the probability of choosing a dedicated CAV lane.

Regarding the surveys mentioned above, users' views of experience with technology can be estimated from survey questions such as smartphone ownership, use of smartphone applications, sentiment about technology (e.g., safety, data security, privacy), etc. Users' preferences for flexibility during travel (e.g., comfort and multitasking) can be inferred from survey questions such as relevance of multitasking during travel, need for comfort, and preference for levels of comfort. Users' preferences for CAVs or shared CAVs if CAVs had a dedicated lane can be evaluated from questions related to previous use of a dedicated corridor and choice of dedicated corridor based on stated benefits. Users' prior experiences with CAVs and/or preferences for CAVs (private or shared CAVs) can be measured by questions regarding same.

Regarding virtual reality (VR) simulations to collect related CAV lane choice behavior data, the VR simulator may differentiate between regular vehicles and CAVs. Dedicated CAV lanes may be visually indicated and when entered effects such as reliability, comfort, handsfree operation, improved travel time, added capacity, safety, and connectivity may become apparent to a test subject. A test run by a user may be preceded by a socio-demographic/prior-AV experience survey. The simulation may iterate through various CAV VR scenarios. The simulations may also be applied to different CAV service types such as CAV BRT and CAV DRT. Different factors may be varied and correlated with captured user behavior. Such factors might include whether a lane is a dedicated CAV lane or a regular lane, familiar and unfamiliar networks, comfort/reliability-related factors such as multitasking or not, as well as varying levels of congestion on the simulated roadway. Other scenarios may be presented for varying levels of travel time reliability and for varying weather conditions and visibility.

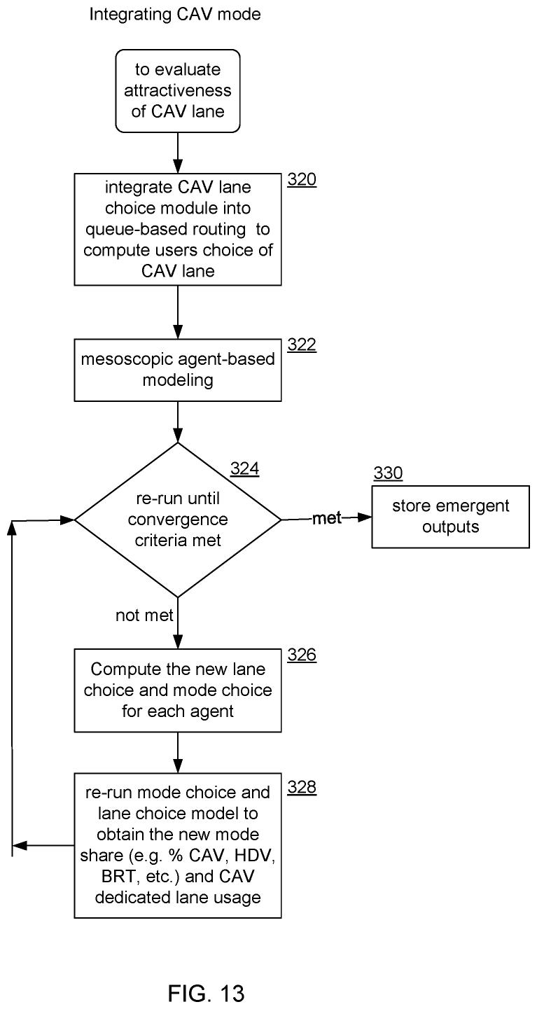

FIG. 13 shows a method for integrating a CAV mode to evaluate the attractiveness of a CAV lane. At step 320 the CAV lane choice module is integrated into queue-based routing to compute a user's choice of a CAV lane. At step 322 the mesoscopic city-scale ABM 102 is executed/simulated. A loop repeats until step 324 determines that convergence has been met. If convergence is not met, then at step 326 a new lane choice and mode is computed choice for each agent. Then, at step 328, the mode-choice and lane-choice model is re-run to obtain a new mode share (e.g., % CAV, HDV, BRT, etc.) and CAV dedicated lane usage. When step 324 determines that convergence has been met, emergent outputs are stored at step 330 for evaluation by designers.

Regarding the emergent outputs, CAV business stakeholders can begin to understand user's preferences for a dedicated CAV lane, and thus the demand for the lane usage prior to making decisions to invest in such infrastructure. The estimated parameters from combined stated preferences and virtual reality surveys and their implications on outputs on simulated models can also inform attributes of dedicated CAV lanes that influence user's choice of the lane. This can be used to integrate distinct features of the dedicated lanes, which has potential to improve usage. Users' preferences for privately owned CAVs and other CAV services (e.g., AV BRT/DRT) can also be evaluated. City-scale demand for CAVs and CAV services can be gauged.

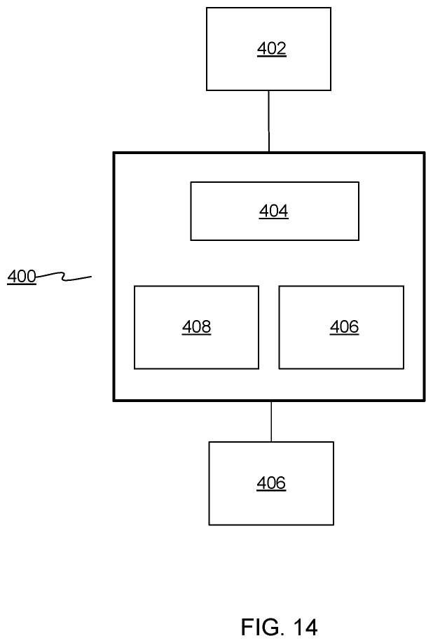

FIG. 14 shows details of a computing device 400, one or more of which may execute the tools and models/simulations discussed above. The technical disclosures herein will suffice for programmers to write software, and/or configure reconfigurable processing hardware (e.g., field-programmable gate arrays (FPGAs)), and/or design application-specific integrated circuits (ASICs), etc., to run on the computing device 400 to implement any of the features or embodiments described herein.

The computing device 400 may have one or more displays 402, a network interface 404 (or several), as well as storage hardware 206 and processing hardware 408, which may be a combination of any one or more: central processing units, graphics processing units, analog-to-digital converters, bus chips, FPGAs, ASICs, Application-specific Standard Products (ASSPs), or Complex Programmable Logic Devices (CPLDs), etc. The storage hardware 406 may be any combination of magnetic storage, static memory, volatile memory, non-volatile memory, optically or magnetically readable matter, etc. The meaning of the term “computer-readable storage”, as used herein does not refer to signals or energy per se, but rather refers to physical apparatuses and states of matter. The hardware elements of the computing device 400 may cooperate in ways well understood in the art of machine computing. In addition, input devices may be integrated with or in communication with the computing device 400. The computing device 400 may have any form-factor or may be used in any type of encompassing device.

In the above disclosure, reference has been made to the accompanying drawings, which form a part hereof, which illustrate specific implementations in which the present disclosure may be practiced. It is understood that other implementations may be utilized, and structural changes may be made without departing from the scope of the present disclosure. References in the specification to “one embodiment,” “an embodiment,” “an example embodiment,” “an example embodiment,” etc., indicate that the embodiment described may include a particular feature, structure, or characteristic, but every embodiment may not necessarily include the particular feature, structure, or characteristic. Moreover, such labels or phrases are not necessarily referring to the same embodiment. Further, when a particular feature, structure, or characteristic is described in connection with an embodiment, one skilled in the art will recognize such feature, structure, or characteristic in connection with other embodiments whether or not explicitly described.

While various embodiments of the present disclosure have been described above, it should be understood that they have been presented by way of example only, and not limitation. It will be apparent to persons skilled in the relevant art that various changes in form and detail can be made therein without departing from the spirit and scope of the present disclosure. Thus, the breadth and scope of the present disclosure should not be limited by any of the above-described example embodiments but should be defined only in accordance with the following claims and their equivalents. The foregoing description has been presented for the purposes of illustration and description. It is not intended to be exhaustive or to limit the present disclosure to the precise form disclosed. Many modifications and variations are possible in light of the above teaching. Further, it should be noted that any or all of the aforementioned alternate implementations may be used in any combination desired to form additional hybrid implementations of the present disclosure. For example, any of the functionality described with respect to a particular device or component may be performed by another device or component. Further, while specific device characteristics have been described, embodiments of the disclosure may relate to numerous other device characteristics. Further, although embodiments have been described in language specific to structural features and/or methodological acts, it is to be understood that the disclosure is not necessarily limited to the specific features or acts described. Rather, the specific features and acts are disclosed as illustrative forms of implementing the embodiments. Conditional language, such as, among others, “can,” “could,” “might,” or “may,” unless specifically stated otherwise, or otherwise understood within the context as used, is generally intended to convey that certain embodiments could include, while other embodiments may not include, certain features, elements, and/or steps. Thus, such conditional language is not generally intended to imply that features, elements, and/or steps are in any way required for one or more embodiments.

1. A method performed by a computing device, the method comprising:
constructing an agent-based model (ABM) that has mesoscopic granularity, the ABM comprising agents, the constructing including incorporating a road network with granularity corresponding to a metropolitan geographical area of interest, wherein the ABM is executed to simulate behavior of the agents, wherein an execution of the ABM produces emergent outputs that correspond to collective effects of simulated individual behaviors of the agents;
the constructing the ABM further comprising implementing a connected autonomous vehicle (CAV) lane-choice behavior model that models CAV lane choice behavior of drivers, the CAV lane-choice behavior model comprising parameters that can be varied to vary lane choice behavior modeled by the lane-choice behavior model;
applying the lane-choice behavior model to the ABM so that when the ABM is executed the simulated agents behave at least in part according to the lane-choice behavior model;
varying the parameters of the lane-choice behavior model, and, for each variation of the parameters, executing the ABM, wherein each execution of the ABM provides a corresponding set of emergent outputs that correspond to a collective behavior of the agents that each behave according to the lane-choice behavior model with a current variation of the parameters; and
storing indicia of the sets of outputs from the ABM.

2. The method according to claim 1, further comprising:
obtaining demand data for the metropolitan geographic area of interest, the demand data comprising daily activity patterns; and
selecting a portion of the demand data corresponding to the metropolitan geographic area of interest.

3. The method according to claim 2, further comprising converting the selected portion of the demand data into a format compatible with the ABM.

4. The method according to claim 3, wherein the converting comprises translating demand statistics into discrete travel instances.

5. The method according to claim 1, wherein the sets of emergent outputs comprise one or more of: expected demand on dedicated CAV lane average consumer wait time, average trip time, average vehicle occupancy, optimal fleet requirement, or road network performance.

6. The method according to claim 1, wherein an execution of the ABM outputs indicia of probabilities that respective users will adopt dedicated CAV lanes modeled in the ABM.

7. The method according to claim 1, wherein the ABM models a CAV service comprising a CAV demand rapid transit (DRT) service or a CAV bus rapid transit service (BRT), and wherein an execution of the ABM outputs an indication of predicted usage of the CAV service.

8. Computer-readable storage hardware storing instructions that, when executed by a computing device, cause the computing device to perform a process, the process comprising:
generating a mesoscopic city-scale ABM comprising agents, the ABM corresponding to a city, the generating comprising:
accessing a road network corresponding to the city and at least an area around the city;
thinning the road network in correspondence to the city such that there a portion of the road network corresponding to the city has higher fidelity than a portion of the road network corresponding to the area around the city;
designating one or more roads in the road network as having dedicated CAV lanes;
incorporating the thinned road network into the ABM;
generating a CAV lane-choice behavior model that models CAV lane-choice behavior of the agents of the ABM; and
incorporating the CAV lane-choice behavior model into the ABM, wherein the CAV lane-choice behavior informs decisions of the agents on whether to use the dedicated CAV lanes.

9. The computer-readable storage hardware according to claim 8, the process further comprising:
obtaining demand data corresponding to the city; and
converting the demand data into discrete travel plans for the agents of the ABM.

10. The computer-readable storage hardware according to claim 9, wherein the demand data comprises summary statistics of travel within, into, and out of the city.

11. The computer-readable storage hardware according to claim 10, wherein the converting the demand data into discrete travel plans comprises converting production-attraction matrices to corresponding origin-destination (OD) trips.

12. The computer-readable storage hardware according to claim 8, wherein the ABM comprises a traffic model that represents CAV impacts on agent decisions.

13. The computer-readable storage hardware according to claim 8, wherein the accessing and thinning of the road network is performed by a network editing tool configured to read road network files of varying formats from varying respective network resources.

14. The computer-readable storage hardware according to claim 13, wherein the network editing tool is further configured to validate and match roadway type, speed, number of lanes on key roadways, or roadway changes due to construction.

15. The computer-readable storage hardware according to claim 16, wherein the network editing tool is further configured to convert the road network into a format compatible with the ABM.

16. A method performed by a computing device, the method comprising:
generating an agent-based model (ABM), the ABM comprising agents, the generating including incorporating a road network corresponding to a metropolitan geographical area of interest, wherein the ABM can be executed to simulate behavior of the agents;
the generating the ABM further comprising a road network to the ABM, the road network comprising designations of CAV-dedicated lanes.
the generating the ABM further comprising implementing a connected autonomous vehicle (CAV) lane-choice behavior model that models CAV lane choice behavior of drivers, the CAV lane-choice behavior model comprising parameters that can be varied to vary lane choice behavior modeled by the lane-choice behavior model;
applying the lane-choice behavior model to the ABM so that when the ABM is executed the simulated agents behave at least in part according to the lane-choice behavior model, and wherein an execution of the ABM outputs probabilities that users modeled by the agents will use the CAV-dedicated lanes.

17. The method according to claim 16, wherein the lane-choice behavior model comprises parameters derived from user surveys.

18. The method according to claim 17, wherein the user surveys comprise virtual reality driving simulations that simulate driving on roads with CAV-dedicated lanes.

19. The method according to claim 16, wherein the ABM models characteristics of the CAV-dedicated lanes.

20. The method according to claim 19, wherein the characteristics comprise lane speed, lane priority, or whether a CAV-dedicated lane is a toll lane.
